(19) United States
(12) Patent Application Publication
(10) Pub. No.: US 2009/0039493 A1
(43) Pub. Date: Feb. 12, 2009

(54) Packaging substrate and application thereof

(75) Inventors: Pao-Hung Chou, Sinfong Township (TW); Chih-Liang Chu, Sinfong Township (TW); Wei-Chun Wang, Sinfong Township (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 12/222,403

(22) Filed: Aug. 8, 2008

(30) Foreign Application Priority Data
Aug. 8, 2007 (TW) 096129161

(51) Int. Cl. H01L 23/49; H05K 1/00

(52) U.S. Cl. 257/686; 257/784; 361/748; 257/E23.024

(57) ABSTRACT

A packaging substrate is disclosed in the present invention, which includes a substrate body having a first surface and an opposite second surface. The first surface has a first cavity, and the second surface has a second cavity. The first cavity corresponds to and is interlinked to the second cavity. In order to provide a space for disposing a chip, the dimension of the second cavity is larger than that of the first cavity, such that there is a step at the interlinking region between the first cavity and the second cavity. Additionally, a plurality of wire bonding pads are disposed on the first surface around the first cavity. A package structure comprising the packaging substrate and the application thereof are also provided in the present invention.

### BACKGROUND OF THE INVENTION

1. Field of the Invention

The present invention relates to a packaging substrate and, more particularly, to a package structure or a stacked package module with reduced height.

2. Description of Related Art

In the development of electronics, the design trend of electronic devices is towards multifunction and high-performance. Thus, high-density integration and miniaturization are necessary for a semiconductor package structure. On the ground of the reason aforementioned, packaging substrates with many active and passive components and circuit connections integrated therein have advanced from being double-layered boards to multi-layered boards by an interlayer connection technique, so as to expand circuit layout space in a limited packaging substrate to thereby meet the demand of the application of high-density integrated circuits and reduce the height of the packaging substrate. Accordingly, more circuits and electronic components per unit volume of the packaging substrate can be arranged therein.

In a general process for manufacturing semiconductor devices, semiconductor chip carriers such as substrates or lead frames suitable for semiconductor devices are first provided by manufacturers. Then, the semiconductor chip carriers are processed by semiconductor chip attachment, wire bonding, encapsulating, implanting solder ball etc. for assembling semiconductor devices. In general, a conventional semiconductor package structure is made such that a semiconductor chip is mounted by its back surface on the top surface of the substrate, then the package structure is finished through wire bonding, or a semiconductor chip is mounted by the active surface thereof on the top surface of the substrate, thereby finishing a flip-chip package structure, followed by placing solder balls on the back surface of the substrate to provide electrical connections for an electronic device like a printed packaging substrate.

FIG. 1 shows a conventional wire bonding package structure. The wire bonding package structure 1 comprises a packaging substrate 10, a chip 12, a plurality of metal wires 14, and a molding material 16. The packaging substrate 10 has a first surface 10a and an opposite second surface 10b having a plurality of wire bonding pads 101 and a plurality of solder pads 102. In addition, the packaging substrate 10 has a cavity 105, and the active surface 12a of the chip 12 is disposed on the first surface and corresponds to the cavity 105. Herein, the active surface 12a of the chip 12 has a plurality of electrode pads 121, electrically connecting to the wire bonding pads 101 of the packaging substrate 10 by the metal wires 14. Besides, the cavity 105 of the packaging substrate 10 is filled with the molding material 16 to encapsulate the metal wires 14 and the active surface 12a of the chip 12. The solder pads 102 of the packaging substrate 10 can electrically connect with an outer electronic device (not shown) by a plurality of solder balls 18.

FIG. 2 shows a stacked package module comprising the aforementioned package structure as shown in FIG. 1. The stacked package module is accomplished by stacking the package structure 1 as shown in FIG. 1 and the package structure 2. Herein, the package structure 2 is another conventional wire bonding package structure. In the package structure 2, the chip 22 is mounted by its back surface on the first surface 20a of the packaging substrate 20, and the electrode pads 221 of the chip 22 electrically connect to the wire bonding pads 201 of the packaging substrate 20 by a plurality of metal wires 24. In addition, the molding material 26 is used in the package structure 2 for encapsulating the chip 22, the metal wires 24 and the wire bonding pads 201. The package structure 1 electrically connects to the package structure 2 by implanting a plurality of solder balls 18 on the solder pads 202 of the packaging substrate 20 and then reflow soldering.

However, in the package module shown in FIG. 2, the fact that the chip 12 of the package structure 1 is mounted on the first surface 10a of the packaging substrate 10 will cause the increase of the height of the package module, and thereby demands of compact and lightweight electronic devices cannot be met.

Accordingly, in order to provide a package structure with reduced thickness, high performance and high flexibility, it is necessary to obviate the aforementioned problems.

### SUMMARY OF THE INVENTION

One object of the present invention is to provide a packaging substrate, a package structure and a stacked package module using the same, where a chip is disposed in the package structure by wire bonding to reduce the height of the package structure.

To achieve the foregoing object, the present invention provides a packaging substrate, comprising: a first substrate body having a first surface and an opposite second surface, where the first surface has a first cavity, the second surface has a second cavity, the first cavity corresponds to and is interlinked to the second cavity, the dimension of the second cavity is larger than that of the first cavity, such that there is a step at the interlinking region between the first cavity and the second cavity to provide a space for disposing a chip, and a plurality of wire bonding pads are disposed on the first surface around the first cavity.

The present invention further provides a package structure, comprising: a first substrate body having a first surface and an opposite second surface, where the first surface has a first cavity, the second surface has a second cavity, the first cavity corresponds to and is interlinked to the second cavity, the dimension of the second cavity is larger than that of the first cavity, such that there is a step at the interlinking region between the first cavity and the second cavity to provide a space for disposing a chip, and a plurality of wire bonding pads are disposed on the first surface around the first cavity; and a chip disposed in the second cavity, where the chip has an active surface having a plurality of electrode pads and facing the first cavity, and the wire bonding pads of the first substrate body electrically connect to the electrode pads of the chip by a plurality of metal wires.

The present invention further provides a stacked package module, comprising:

a first package structure comprising a first substrate body having a first surface and an opposite second surface, where the first surface has a first cavity, the second surface has a second cavity, the first cavity corresponds to and is interlinked to the second cavity, the dimension of the second cavity is larger than that of the first cavity, such that there is a step at the interlinking region between the first cavity and the second cavity to provide a space for disposing a chip, and a plurality of wire bonding pads are disposed on the first surface around the first cavity; and a first chip disposed in the second cavity, where the first chip has an active surface having a plurality of electrode pads and facing the first cavity, and the wire bonding pads of the first substrate body electrically connect to the electrode pads of the first chip by a plurality of metal wires; and a second package structure comprising a second substrate body, a second chip and a plurality of second solder pads, where the second solder pads have a plurality of solder balls disposed thereon and electrically connect to the first package structure by the solder balls.

The aforementioned packaging substrate, package structure and stacked package module using the same can further comprise a plurality of first solder pads disposed on the first surface or the second surface of the first substrate body. Herein, the first solder pads can connect to the solder balls of the second package structure and electrically connect to the second solder pads of the second package structure by the solder balls.

The aforementioned package structure and stacked package module can further comprise a molding material filling the first cavity to encapsulate the wire bonding pads, the metal wires and the active surface of the first chip.

In the present invention, the second package structure can be any package structure, for example, a wire bonding package structure or a package structure with a second chip embedded therein.

Other objects, advantages, and novel features of the invention will become more apparent from the following detailed description when taken in conjunction with the accompanying drawings.

### BRIEF DESCRIPTION OF THE DRAWINGS

FIG. 1 shows a conventional wire bonding package structure;

FIG. 2 shows a conventional stacked package module;

FIG. 3 shows a package structure according to Embodiment 1 of the present invention;

FIG. 4 shows a package structure according to Embodiment 2 of the present invention;

FIG. 5 shows a stacked package module according to Embodiment 3 of the present invention;

FIG. 6 shows a stacked package module according to Embodiment 4 of the present invention;

FIG. 7 shows a stacked package module according to Embodiment 5 of the present invention; and

FIG. 8 shows a stacked package module according to Embodiment 6 of the present invention.

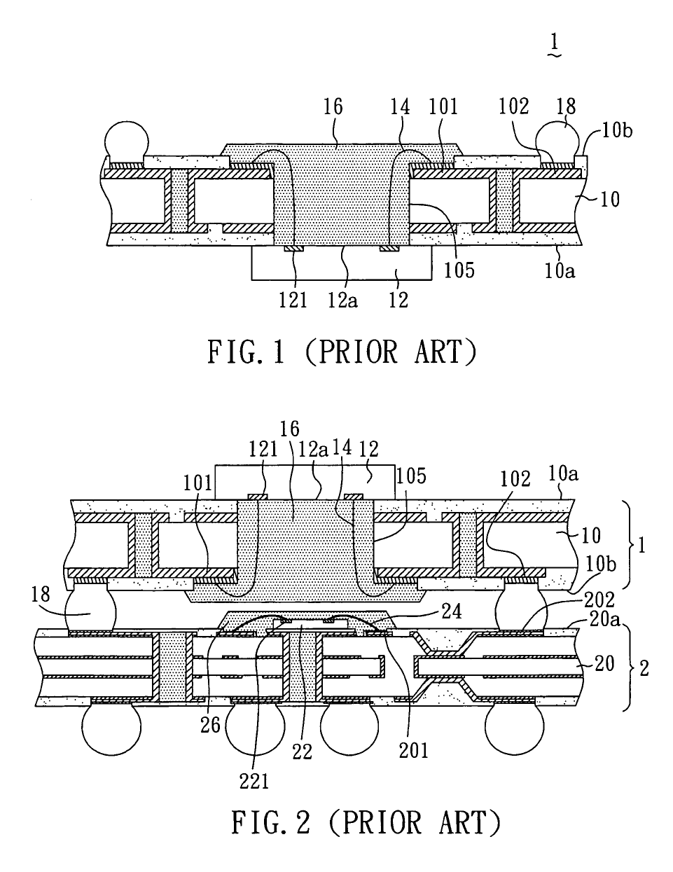

### DETAILED DESCRIPTION OF THE PREFERRED EMBODIMENT

Because the specific embodiments illustrate the practice of the present invention, a person having ordinary skill in the art can easily understand other advantages and efficiency of the present invention through the content disclosed therein. The present invention can also be practiced or applied by other variant embodiments. Many other possible modifications and variations of any detail in the present specification based on different outlooks and applications can be made without departing from the spirit of the invention.

### Embodiment 1

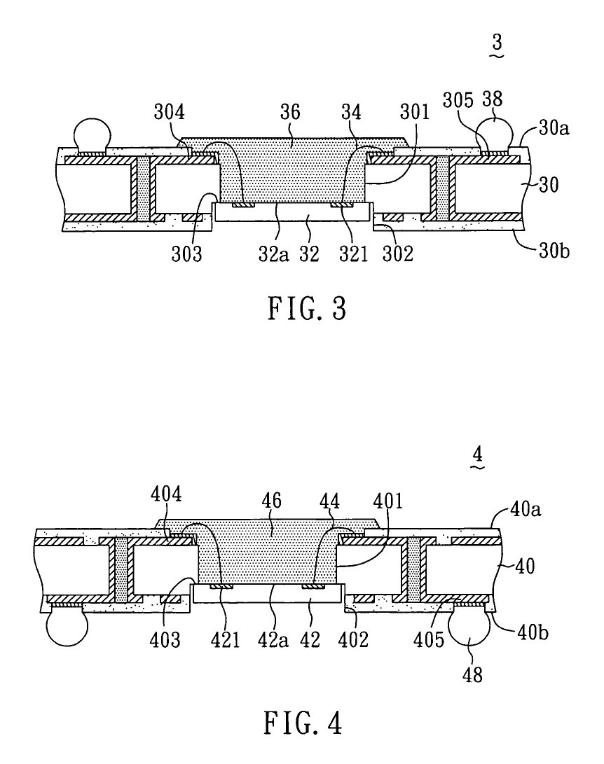

With reference to FIG. 3, there is shown a cross-section view of a package structure according to the present embodiment. In the present embodiment, the first package structure 3 comprises a first substrate body 30 and a first chip 32. The first substrate body 30 has a first surface 30a and an opposite second surface 30b. Herein, the first surface 30a has a first cavity 301, and the second surface 30b has a second cavity 302. The first cavity 301 corresponds to and is interlinked to the second cavity 302, and the dimension of the second cavity 302 is larger than that of the first cavity 301, such that there is a step 303 at the interlinking region between the first cavity 301 and the second cavity 302 to provide a space for disposing a chip, and a plurality of wire bonding pads 304 are disposed on the first surface 30a around the first cavity 301. The first chip 32 is disposed in the second cavity 302 of the first substrate body 30, and the first chip 32 has an active surface 32a with a plurality of electrode pads 321 thereon. Herein, the active surface 32a faces the first cavity 301. Besides, the wire bonding pads 304 of the first substrate body 30 electrically connect to the electrode pads 321 of the first chip 30 by a plurality of metal wires 34.

Additionally, the first surface 30a further has a plurality of solder pads 305 thereon, and a plurality of solder balls 38 are disposed on the solder pads 305. Furthermore, the first cavity 301 is filled with a molding material 36 to encapsulate the wire bonding pads 304, the metal wires 34 and the active surface 32a of the first chip 32.

In the present embodiment, the materials of the wire bonding pads 301 and the solder pads 305 are individually selected from the group consisting of copper, silver, gold, nickel/gold, nickel/palladium/gold and a combination thereof.

### Embodiment 2

With reference to FIG. 4, there is shown a cross-section view of a package structure according to the present embodiment. The first package structure 4 provided by the present embodiment is the same as the first package structure 3 provided by Embodiment 1, except that the solder pads 405 of the first package structure 4 according to the present embodiment are disposed on the second surface 40b. Accordingly, in the first package structure 4 of the present embodiment, the solder balls 18 disposed on the solder pads 405 are at the same side as the first chip 42.

### Embodiment 3

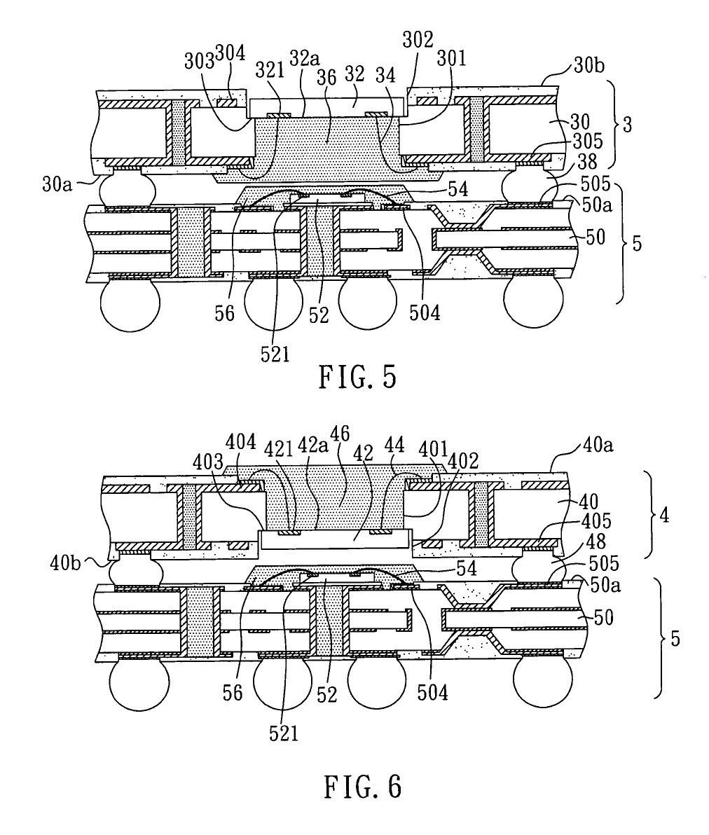

With reference to FIG. 5, there is shown a cross-section view of a stacked package module according to the present embodiment. In the present embodiment, a wire bonding package structure is used as the second package structure 5, and the first package structure 3 illustrated in Embodiment 1 is disposed on the second package structure 5. Herein, the second chip 52 of the second package structure 5 is mounted by its back on the first surface 50a of the second substrate body 50, and the electrode pads 521 of the second chip 52 electrically connect to the wire bonding pads 504 of the second substrate body 50 by the metal wires 54. In addition, a molding material 56 is used to encapsulate the second chip 52, the wire bonding pads 504 and the metal wires 54. In the stacked package module of the present embodiment, a plurality of solder balls 38 is used for the electrical connection between the solder pads 305 of the first package structure 3 and the solder pads 505 of the second package structure 5.

In the first package structure 3 of the present invention, there is a step 303 at the interlinking region between the first cavity 301 and the second cavity 302 to provide a space for disposing a chip. Accordingly, the height of the package structure can be reduced.

### Embodiment 4

With reference to FIG. 6, there is shown a cross-section view of a stacked package module according to the present embodiment. In the present embodiment, the package structure illustrated in Embodiment 2 is used as the first package structure 4, and the package structure illustrated in Embodiment 3 is used as the second package structure 5. In the stacked package module of the present embodiment, the first package structure 4 is disposed on the second package structure 5, and the solder pads 405 of the first package structure 4 electrically connect to the solder pads 505 of the second package structure 5 by a plurality of solder balls 48.

As shown in FIG. 6, in the first package structure 4 of the present invention, there is a step 403 at the interlinking region between the first cavity 401 and the second cavity 402 to provide a space for disposing a chip. Accordingly, the height of the package structure can be reduced. Furthermore, since the first chip 42 of the first package structure 4 is at the same side as the solder balls 48, the distance between the first package structure 4 and the second package structure 5 only depends on the height of the molding material 56 of the second package structure 5, and not on the height of the molding material 46 of the first package structure 4.

### Embodiment 5

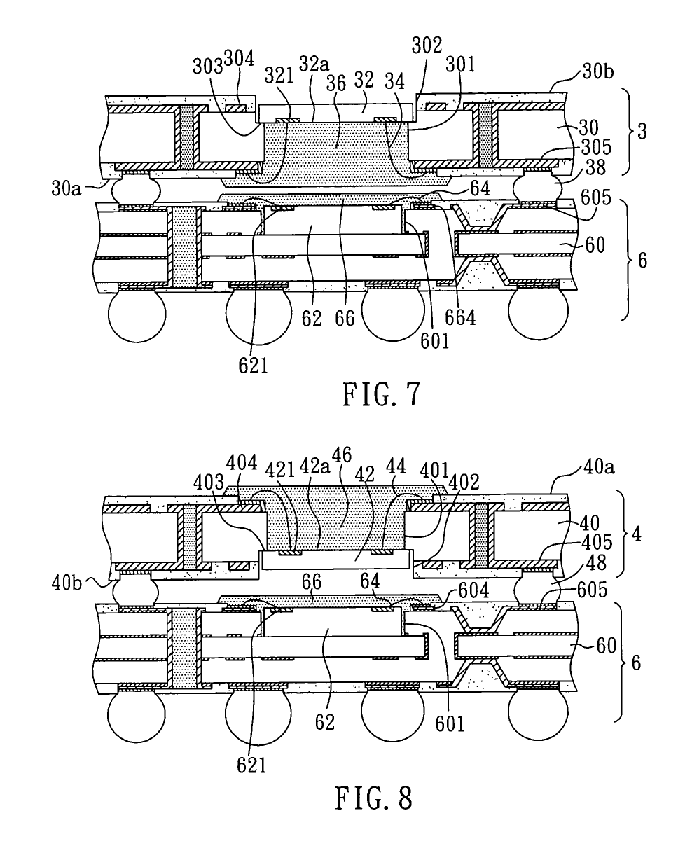

With reference to FIG. 7, there is shown a cross-section view of a stacked package module according to the present embodiment. In the present embodiment, the package structure illustrated in Embodiment 1 is used as the first package structure 3, and a package structure with a chip embedded therein is used as the second package structure 6. In the stacked package module of the present embodiment, the first package structure 3 illustrated in Embodiment 1 is disposed on the second package structure 6.

Herein, the second chip 62 of the second package structure 6 is disposed by its back in the cavity 601 of the packaging substrate 60, and the electrode pads 621 of the second chip 62 electrically connect to the wire bonding pads 604 of the second packaging substrate 60 by the metal wires 64. In addition, a molding material 66 is used to encapsulate the second chip 62, the wire bonding pads 604 and the metal wires 64. In the stacked package module of the present embodiment, a plurality of solder balls 38 is used for the electrical connection between the solder pads 305 of the first package structure 3 and the solder pads 605 of the second package structure 6.

In the first package structure 3 of the present invention, there is a step 303 at the interlinking region between the first cavity 301 and the second cavity 302 to provide a space for disposing a chip. Accordingly, the height of the package structure can be reduced.

### Embodiment 6

With reference to FIG. 8, there is shown a cross-section view of a stacked package module according to the present embodiment. In the present embodiment, the package structure illustrated in Embodiment 2 is used as the first package structure 4, and the package structure illustrated in Embodiment 5 is used as the second package structure 6. In the stacked package module of the present embodiment, the first package structure 4 is disposed on the second package structure 6, and the solder pads 405 of the first package structure 4 electrically connect to the solder pads 605 of the second package structure 6 by a plurality of solder balls 48.

As shown in FIG. 8, in the first package structure 4 of the present invention, there is a step 403 at the interlinking region between the first cavity 401 and the second cavity 402 to provide a space for disposing a chip. Accordingly, the height of the package structure can be reduced. Furthermore, since the first chip 42 of the first package structure 4 is at the same side as the solder balls 48, the distance between the first package structure 4 and the second package structure 6 only depends on the height of the molding material 66 of the second package structure 6, and not on the height of the molding material 46 of the first package structure 4.

Accordingly, in the present invention, the chip and the solder balls can be at the same side or opposite side to thereby variously design the arrangement of circuits in the package structure. In addition, in the present invention, the height of the package structure can be reduced by forming a step at the interlinking region between the first cavity and the second cavity to provide a space for disposing a chip.

Although the present invention has been explained in relation to its preferred embodiment, it is to be understood that many other possible modifications and variations can be made without departing from the scope of the invention as hereinafter claimed.

What is claimed is:

1. A packaging substrate, comprising:
a first substrate body having a first surface and an opposite second surface, wherein the first surface has a first cavity, the second surface has a second cavity, the first cavity corresponds to and is interlinked to the second cavity, the dimension of the second cavity is larger than that of the first cavity, such that there is a step at the interlinking region between the first cavity and the second cavity to provide a space for disposing a chip, and a plurality of wire bonding pads are disposed on the first surface around the first cavity.

2. The packaging substrate as claimed in claim 1, further comprising a plurality of solder pads disposed on the first surface or the second surface.

3. A package structure, comprising:
a first substrate body having a first surface and an opposite second surface, wherein the first surface has a first cavity, the second surface has a second cavity, the first cavity corresponds to and is interlinked to the second cavity, the dimension of the second cavity is larger than that of the first cavity, such that there is a step at the interlinking region between the first cavity and the second cavity to provide a space for disposing a chip, and a plurality of wire bonding pads are disposed on the first surface around the first cavity; and
a first chip disposed in the second cavity, wherein the first chip has an active surface having a plurality of electrode pads and facing the first cavity, and the wire bonding pads of the first substrate body electrically connect to the electrode pads of the first chip by a plurality of metal wires.

4. The package structure as claimed in claim 3, further comprising a plurality of solder pads disposed on the first surface or the second surface.

5. The package structure as claimed in claim 3, further comprising a molding material filling the first cavity to encapsulate the wire bonding pads, the metal wires and the active surface of the first chip.

6. A stacked package module, comprising:
a first package structure comprising a first substrate body having a first surface and an opposite second surface, wherein the first surface has a first cavity, the second surface has a second cavity, the first cavity corresponds to and is interlinked to the second cavity, the dimension of the second cavity is larger than that of the first cavity, such that there is a step at the interlinking region between the first cavity and the second cavity to provide a space for disposing a chip, and a plurality of wire bonding pads are disposed on the first surface around the first cavity; and a first chip disposed in the second cavity, wherein the first chip has an active surface having a plurality of electrode pads and facing the first cavity, and the wire bonding pads of the first substrate body electrically connect to the electrode pads of the first chip by a plurality of metal wires; and
a second package structure comprising a second substrate body, a second chip and a plurality of second solder pads, wherein the second solder pads have a plurality of solder balls disposed thereon and electrically connect to the first package structure by the solder balls.

7. The stacked package module as claimed in claim 6, further comprising a plurality of first solder pads disposed on the first surface or the second surface, wherein the first solder pads connect to the solder balls of the second package structure and electrically connect to the second solder pads of the second package structure by the solder balls.

8. The stacked package module as claimed in claim 6, further comprising a molding material filling the first cavity to encapsulate the wire bonding pads, the metal wires and the active surface of the first chip.

9. The stacked package module as claimed in claim 6, wherein the second package structure is a wire bonding package structure.

10. The stacked package module as claimed in claim 6, wherein the second chip is embedded in the second package structure.
